(19) United States
(12) Patent Application Publication
(10) Pub. No.: US 2004/0217771 A1
(43) Pub. Date: Nov. 4, 2004

(54) Probe for integrated circuit test socket

(76) Inventor: Tan Yin Leong, Singapore (SG)

Correspondence Address: George D. Liu, Lawrence Y D Ho & Associates, PMB 400, 2101 Crystal Plaza Arc, Arlington, VA, 22202, US

(21) Appl. No.: 10/829,195

(22) Filed: Apr. 22, 2004

(30) Foreign Application Priority Data
Apr. 29, 2003 (SG) 200302373-6

(51) Int. Cl. G01R 31/02

(52) U.S. Cl. 324/754

(57) ABSTRACT

An improved probe for use in test sockets of automatic test equipment for packaged integrated circuits that allows longer intervals between replacement of equipment components is described. The present invention has a plurality of contact points available to contact a trace of the test equipment allowing circuitry with worn traces to remain serviceable for a longer period of use. The present invention also has a toothed contact arm to allow for easier cleaning of solder accumulation and a secondary support to reduce impact on spring elements of the test socket.

### FIELD OF THE INVENTION

The present invention relates to an improved probe for an integrated circuit (IC:) test socket.

In particular, this invention relates to an improved probe having a plurality of contact points to accommodate wear in contact traces of printed circuit boards (PCBs) in test sockets of IC test equipment.

### BACKGROUND OF THE INVENTION

Integrated circuits, commonly known as ICs or “chips”, have to be tested after manufacture for quality control. These ICs may be tested directly on the wafer on which they are fabricated or after they have been packaged or sealed in a carrier package. Packaged ICs have leads that allow electrical connection between themselves and the devices they are installed in. Alternatively, packaged ICs may also be leadless and electrical connection to other devices is through pads, bumps or lands on the outside of the package.

Automatic test equipment (ATE) for packaged ICs have means of temporarily holding the ICs and bringing their leads (for leaded chips) or other contact points (the pads, bumps and lands of leadless chips) into electrical contact with the test circuitry, which is usually in the form of a printed circuit board or PCB.

In most test apparatuses, an electrical connection, called a contactor or probe, is used as the intermediary between the lead or pad of the IC (or device under test, DUT) and the test circuitry. The point of electrical connection by the probe on the test circuitry is part of an exposed, un-insulated conductive path called a trace. Traces connect different components of the PCB to each other. By bridging the DUT and the test circuitry, the probe allows test signals to be transmitted between the DUT and the test circuitry.

After the test has been performed, the DUT is removed from the socket and faulty ICs are rejected. One test iteration thus involves the insertion of the IC into the test socket, testing of the IC and removal of the IC from the test socket after testing.

The intermediate contactors or probes in the test socket come in different designs. They may be spring-loaded “Pogo” contactors or s- or z-shaped probes, depending on the design of the test socket and the type of connection (lead or pad) on the DUT.

U.S. Pat. No. 5,594,355 (Ludwig) is an example of an electrical probe of the latter s- or z-shaped design for use in a test socket for testing integrated circuit devices (FIG. 1). In such test sockets, there is usually one probe for each lead or pad of the packaged IC. Insertion of the IC into the test socket will cause each lead or pad to engage and press down on one part of the probe. The part of the probe that engages the IC lead or pad is the arm.

Insertion of the IC enables electrical signals to be passed between the IC and the test circuitry. Insertion of the IC also compresses one or more elastomeric or spring elements in the test socket that ensure good electrical connection between the IC and the test circuitry by forcing the probe against the IC's lead or pad.

The part of the probe that contacts the PCB trace is the contact point.

U.S. Pat. No. 5,594,355 also mentioned that probes should be designed such that the connection path between IC and PCB is as short as possible to minimize undesirable electrical characteristics such as increased electrical resistance. This is especially important for the high frequency testing of modern ICs.

Several problems in such probes of the prior art were listed by that patent. These include wear and damage of the trace caused by repeated insertion of the IC leading to cost in terms of money and time to replace PCBs due to wear and tear. As the probe bears down on the trace of the PCB, it “wipes” or cuts into the trace, wearing the trace, and the probe itself, at that point of contact. Even as replacement probes can be replaced, they also need to be aligned in the test socket before use.

U.S. Pat. No. 5,594,355 addresses these problems in the prior art by having means to quickly access the probes to allow quick replacement, and providing slots to maintain alignment of the probes in the test socket.

Another problem in practice is that of transfer of solder from the IC leads to the probes. This accumulation of solder on the probe can cause increased electrical resistance at the point of contact with the lead of the IC. This contamination by solder needs to be cleaned off periodically.

Yet another problem is having to replace the elastomeric or spring elements when they are worn out.

While reducing the time and cost of replacing the probes is desirable, other improvements can still be made to reduce the cost of operating such ATE. Further improvements may be made to the design of the probe to overcome the problem of wear and tear of the PCB trace in contact with the probe. In addition, a probe design that facilitates the cleaning of solder contamination will also be welcome as will a design that allows the elastomeric elements to have a longer useful life-span.

Therefore, a need clearly exists for an improved probe that enables a longer mean time between replacement of probe, PCB and elastomeric elements that will lower costs. The overall speed of testing ICs will also be increased as the frequency of shutting down test equipment to replace PCBs is reduced. Overall, an improved probe that can reduce the frequency between having to replace itself, the PCB or elastomeric elements will lead to savings in time and cost.

### SUMMARY OF THE INVENTION

The present invention is a probe for connecting a device under test with at least one trace of a test circuitry comprising:

a body;

a contact area with a plurality of contact points to contact said at least one trace;

at least one arm for engaging at least one contact point of said device under test;

at least one means of receiving at least one spring means; and

at least secondary support means

whereby probe can maintain electrical contact with said at least one trace as said at least one trace is worn with use.

In particular, the present invention is a probe for connecting an integrated circuit with a trace of test circuitry with a body shaped to fit a test socket, a plurality of contact points, a toothed arm for engaging a lead or pad of an integrated circuit under test, a notch to receive one or more elastomeric means and a curved leg to provide secondary support for the insertion of integrated circuit.

### BRIEF DESCRIPTION OF THE DRAWINGS

A preferred embodiment of the present invention will now be more fully described, by way of example, with reference to the drawings. Some details have been intentionally omitted for clarity, and dimensions, shapes and angles may have been exaggerated to illustrate the invention.

FIG. 1A illustrates probe designs of the prior art as exemplified by U.S. Pat. No. 5,594,355 while FIG. 1B is an exploded view of a typical test socket using s- or z-shaped probes of the prior art;

FIG. 2 shows the cross-sectional view of a typical test socket with the improved probe of the present invention installed;

FIG. 3A-C is the sequence of events showing how the present invention of an improved probe works while FIG. 3D shows a side-by-side comparison between a probe of the state of the art and the improve probe of the present invention; and

FIGS. 4A-C are several embodiments of the present invention of an improved probe.

### DETAILED DESCRIPTION of the DRAWINGS

In accordance with the figures, a preferred embodiment of the invention is described. In the following description, details are provided to describe the preferred embodiment. It shall be apparent to one skilled in the art, however, that the invention may be practiced without such details. Some of these details may not be described at length so as not to obscure the invention.

It is an object of the present invention to provide a probe that allows longer intervals between replacement of the printed circuit board (PCB), spring elements or probes in automatic test equipment (ATE) for packaged integrated circuits.

There are many advantages of the present invention over probes of the prior art. One advantage of the present invention is that multiple contact points are available in the present invention to contact the trace of the PCB. As the trace is worn at a particular point, subsequent insertions of the DUT into the test socket will cause the probe to rotate slightly and contact another fresh, un-eroded point on the trace at another point of contact of the probe. This design of the present invention provides a plurality of such contact points and thus advantageously extends the useful life span of both the probe and the PCB before they need to be replaced.

Another advantage is that, in one embodiment, the contact area of the probe with the lead or pad of the device under test (DUT) is toothed allows easy cleaning of that contact area to remove solder deposited by the lead at each insertion of the DUT.

While the following description of the DUT is for a leaded IC, the present invention is also understood to be also applicable for use in the testing of leadless IC where the arm of the probe contacts a pad, bump or land of such leadless ICs.

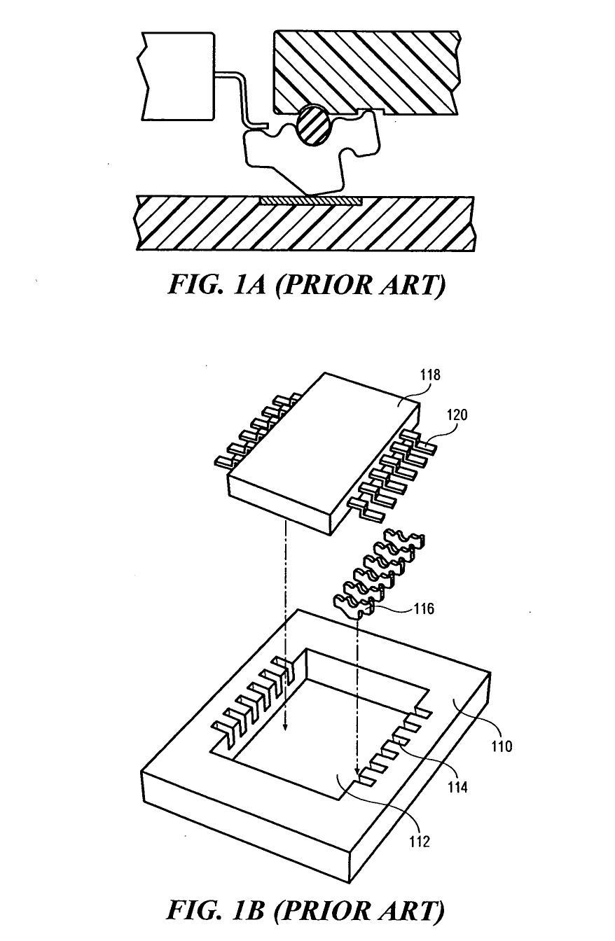

FIG. 1B is an exploded view showing part of a typical IC test socket of the prior art comprising a housing 110 with a recess 112 to accept the DUT 118, and slots 114 to hold the probes 116. In a test iteration, an IC which is the DUT 118, is brought by a part of the automatic test equipment (ATE; not shown) and fitted into the recess 112 where its leads 120 can contact the probes 116.

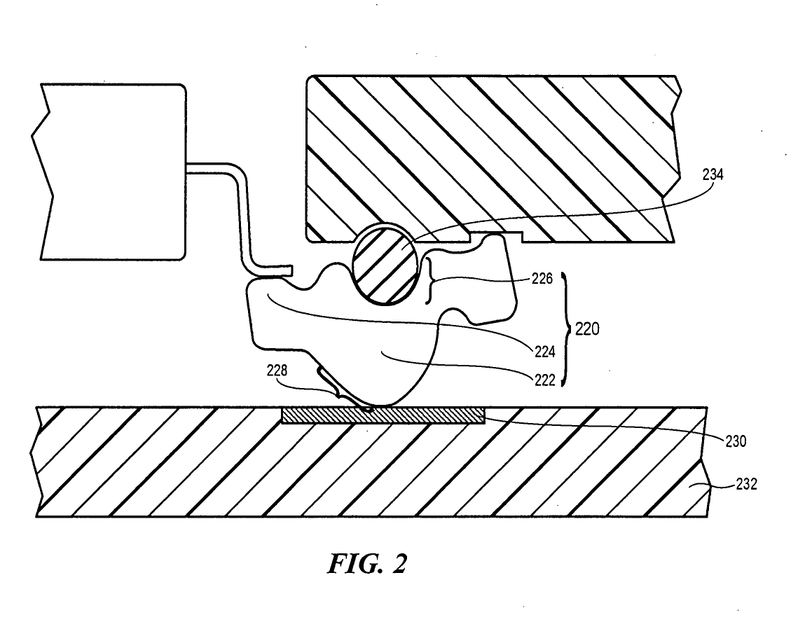

FIG. 2A is a cross-sectional view of part of the IC test socket showing the preferred embodiment of the improved probe 220 of the present invention installed in place. In the preferred embodiment, the improved probe has a body 222 made of copper-beryllium although any suitable electrically-conductive material including, but not limited to, pure or alloyed metals such as gold, silver, copper rhodium, nickel and palladium, and electrically-conductive non-metals may also be used.

The improved probe is seen to have an arm 224 that contacts the respective lead of the DUT after the DUT is lowered or inserted into the test socket.

The improved probe also has a fulcrum which is a notch 226 on which it receives and pivots on one or more elastomerical elements 234, and a continuous curvilinear edge 228 that provides a plurality of contact points to contact the trace 230 of the PCB 232. The elastomeric elements 234 are the spring means that ensure good contact between the arm 224 of the probe and the lead of the DUT.

As such, in circumstances where the spring means is not an elastomeric element, the notch will be a suitable means of receiving and engaging the spring means of choice. This variation is within the scope of the present invention. However, the elastomeric elements or other spring means as the case may be, are part of the test socket and hence are not elements of the present invention.

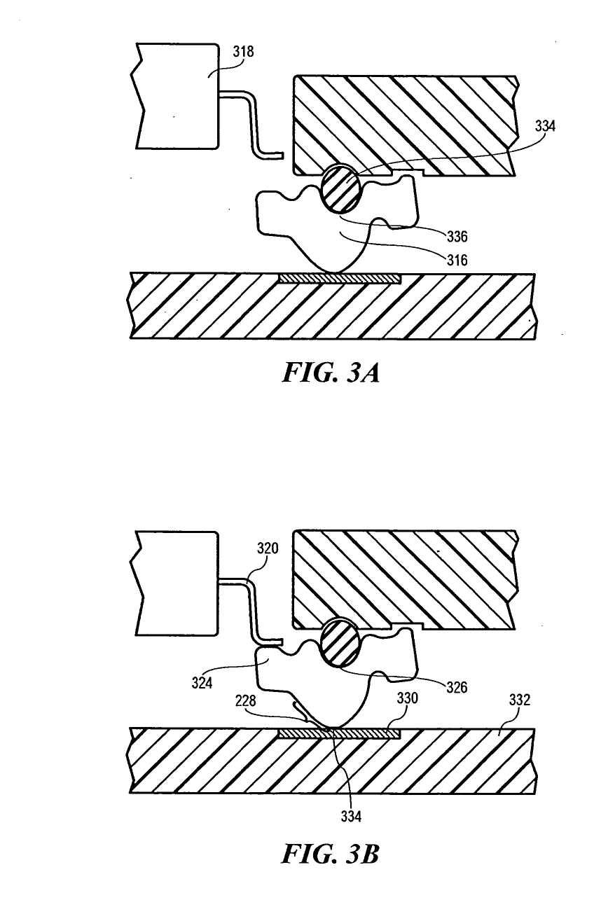

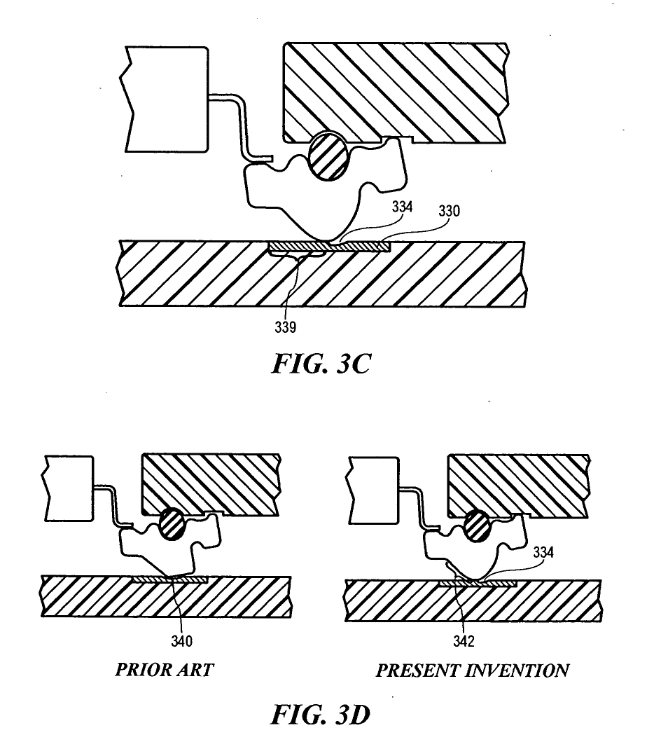

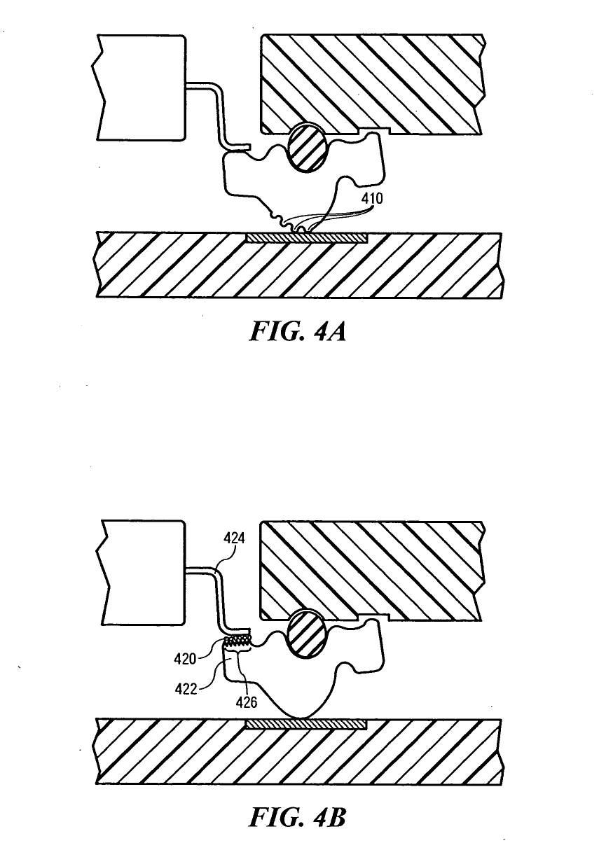

The sequential cross-sectional drawings in FIGS. 3A-C of the test socket show how the present invention works. In FIG. 3A, the DUT 318 is about to be inserted into the recess of the test socket. The improved probe 316 is in its uncontacted position and the elastomeric element 334 is in its notch 336, is only slightly compressed.

In FIG. 3B, the DUT is fully inserted into the recess of the test socket. Each lead 320 engages the arm 324 of their respective probe, forcing each contacted probe to rotate slightly on its fulcrum 326, swiping or wiping the continuous curvilinear edge 328 with the trace 330 with the PCB 332, and thereby connecting that lead 320 of the DUT to the test circuitry. It can be seen that as the probe is thin, this point of contact resembles a knife edge that cut or gouge into the trace 330 of the PCB by the wiping action caused by the slight rotation of the probe. This erodes the trace at the first point of contact 334. The trace is susceptible to wear as it is usually made of copper material plated with a thin layer of gold, which is relatively softer than the copper-beryllium used for the probe.

FIG. 3C shows the trace 330 of the PCB worn down (at position 334) after many test iterations. However, as the trace wears, the improved probe of the present invention rotates further to maintain contact with fresh, unworn areas 339 of the trace. As the width of the PCB's trace 330 is narrow, the degree of rotation, and hence the increased depth of insertion of the DUT, are also small and within the range experienced during normal operations of the ATE.

FIG. 3D is a side-by-side comparison of a probe of the state of the art and the improve probe of the present invention highlighting the differences between the two probes. Unlike the single sharp contact point 340 of a probe of the state of the art, the improved probe has a continuous curvilinear edge 342 providing a plurality of possible contact points to connect to the trace, allowing the trace to remain serviceable despite being worn at previous contact points 334.

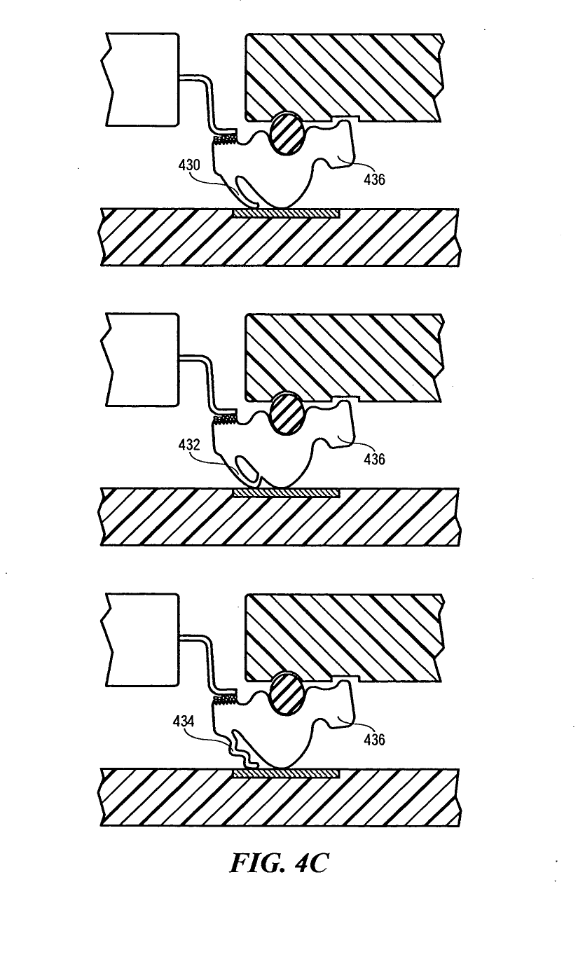

While a continuous curvilinear edge for the probe is used in the preferred embodiment of the present invention, a plurality of bumps forming discrete contact points 410 is also possible in another embodiment of the present invention (FIG. 4A).

Thus, it can be seen that the present invention of using a curvilinear edge to provide a plurality of contact points is advantageous. However, various difficulties have had to be overcome in the present invention. For example, the degree of curvature of the continuous contact edge has to be carefully determined to ensure smooth contact as the probe rotates about its fulcrum. If the curve is too gentle, it approximates a large, single contact point and a larger area of the trace may be worn out at the same time, obviating the benefits of the present invention. Thus, the curvature of the contact edge must be carefully determined.

Also, as the improve probe rotates to accommodate wear in the trace, the depth at which the DUT must be inserted or seated into the socket has to be increased. This is usually within the normal operating range of the ATE. However, in some ATE that cannot accommodate this slight increase in depth of insertion, the insertion mechanism of the test apparatus may have to be fine-tuned as necessary.

Eventually, the wear of the PCB trace and probe may arrive at an unacceptable level. At this time, the PCB and probe should be replaced.

As may be seen in FIG. 4B, the present invention also addresses the problem of solder accumulation at the point of contact between the arm 422 of the probe in contact with the lead 424 of the DUT. In probes of the state of the art, the accumulated solder, having a lower electrical conductivity than the lead of the DUT or the arm of the probe, degrades the testing of the DUT. Under the state of the art, this accumulated solder has to be periodically removed by laborious cleaning.

The present invention has a plurality of teeth 426 formed on the arm 422 of the improved probe at the point of contact with the lead. When any solder 420 is deposited on the teeth 426 after one test iteration, the smaller surface area at the peaks of the teeth will allow easier subsequent removal of the solder as the surface area available for the solder to adhere to is smaller than that of probes of the state of the art.

While the plurality of teeth 426 are shown to be disposed perpendicular to the longitudinal axis of the arm, they may also be disposed parallel or diagonal to the longitudinal axis of the arm. As the inventive step is to have a small surface area to permit easier cleaning of any accumulated solder, any other design to reduce the surface area, such as cross-hatching or the plurality of teeth described, are within the scope and spirit of the invention.

On the problem of the spring means or elastomeric elements wearing out, a secondary support element (FIG. 4C) may be provided on the improved probe to reduce the shock and wear-and-tear on the elastomeric elements upon insertion of the IC. This secondary support element may take shape as a curved leg 430 or a loop 432, or a W-shaped leg 434 extending from the body 436 of the probe. By dampening the shock on the elastomeric elements, their useful life spans may be increased and the interval to replace them lengthened.

Thus, it can be appreciated that features of the present invention such as the plurality of contact points providing longer operating life span of the probe and its toothed feature on the arm to allow easier cleaning of accumulated solder, and the availability of a secondary support element are inventive. The beneficial effects of allowing the probe, PCB and elastomeric elements to be used beyond their normal expected life-spans, make the improved probe an ideal replacement for existing designs of probes.

These features of the improved probe may require different hardness of beryllium copper. For example, the secondary support element may be made less hard and hence more “springy” while the teeth of the lead contact arm should be hardened to allow easier removal of any accumulated solder. As copper cannot be hardened by heat treatment but only by alloying it with other metals or elements, parts made of beryllium copper of different hardness may be fused together for the different features of the improved probe. Alternatively, other suitable materials may be used for each feature of the improved probe such as heat-treatable metal for the toothed arm or composite materials for the secondary support element.

To fit existing test sockets, the improved probe may be varied in its dimensions while retaining its features such as the curvilinear continuous contact edge, toothed contact arm and secondary support element without departing from the scope of the present invention.

It will be appreciated that although only a few preferred embodiments have been described in detail, various modifications and improvements can be made by a person skilled in the art without departing from the scope of the present invention. Various suitable equivalent materials may also be used to fabricate the probe under the present invention.

1. A probe for connecting a device under test with at least one trace of a test circuitry comprising:
a body;
a contact area with a plurality of contact points to contact said at least one trace;
at least one arm for engaging at least one lead of said device under test;
at least one means of receiving at least one spring means;
and
at least secondary support means
whereby
probe can maintain electrical contact with said at least one trace as said at least one trace is worn with use.

2. A probe according to claim 1, wherein shape of said body may be varied to enable said probe to fit in a test socket.

3. A probe according to claim 1, wherein said plurality of contact points may on a continuous curve.

4. A probe according to claim 1, wherein said plurality of contact points may discrete bumps on said contact area.

5. A probe according to claim 1, wherein contact area of said arm engaging said lead is toothed.

6. A probe according to claim 1, wherein contact area of said arm engaging said lead is cross-hatched.

7. A probe according to claim 1, wherein said at least one means of receiving at least one spring means is a notch.

8. A probe according to claim 1, wherein said at least secondary support means is a curved leg.

9. A probe according to claim 1, wherein said at least secondary support means is a loop.

10. A probe according to claim 1, wherein said at least secondary support means is W-shaped.
